(19) United States
(12) Patent Application Publication
(10) Pub. No.: US 2010/0282311 A1
(43) Pub. Date: Nov. 11, 2010

(54) Solar Cell Device Having Low Electrical and Thermal Impedance

(75) Inventor: Chih-Hung Wu, Longtan Shiang (TW)

Correspondence Address: Jackson Intellectual Property Group PLLC, 106 Starvale Lane, Shipman, VA, 22971, US

(73) Assignee: ATOMIC ENERGEY COUNCIL-INSTITUTE OF NUCLEAR ENERGY RESEARCH, Lungtan (TW)

(21) Appl. No.: 12/637,424

(22) Filed: Dec. 14, 2009

(30) Foreign Application Priority Data
May 7, 2009 (TW) 098115079

(51) Int. Cl. H01L 31/02

(52) U.S. Cl. 136/256

(57) ABSTRACT

A solar cell is fabricated. Its light-absorbing part is close to a heat-diffusing device. Thus, the solar cell has low electrical and thermal Impedance. The solar cell has a strong structure, high efficiency and is fit for mass production.

### FIELD OF THE INVENTION

The present invention relates to a solar cell device; more particularly, relates to adhering a light absorption region to a heat dissipation device for reducing an electric resistance and a thermal resistance with strong structure and high efficiency.

### DESCRIPTION OF THE RELATED ARTS

A general solar cell device, as shown in FIG. 5, comprises a thin substrate 4 and a plurality of electric contact pads 5 deposed above the substrate 4, where the solar cell device can be adhered to a heat dissipation device 7 by using a bonding agent on a lower flat surface of the substrate 4.

However, the above structure requires a complex procedure. For example, since the substrate 4 is weak during wire bonding on wafer, an extra substrate is needed for bonding; but the same extra substrate is removed later. As a result, the fabricating time is prolonged and is not good for mass production. In addition, the whole structure does not have enough heat dissipation efficiency. Hence, when the device is used under a high condensing light, heat is greatly aggregated and so the device is reduced in efficiency and even in life of use. Hence, the prior art does not fulfill all users' requests on actual use.

### SUMMARY OF THE INVENTION

The main purpose of the present invention is to adhere a light absorption region of a solar cell to a heat dissipation device for reducing an electric resistance and a thermal resistance with strong structure and high efficiency.

To achieve the above purpose, the present invention is a solar cell device having low electrical and thermal impedance, comprising a substrate, a plurality of electric contact pads and an ohmic contact, where the substrate has an upper surface and a lower surface; the lower surface is corresponding to the upper surface; the substrate has a recessed hole on the lower surface; the recessed hole has openings connected with four recessed channels; the recessed hole comprises a central recess and a recess sidewall; the recess sidewall surrounds the central recess; the electric contact pads is deposed on the upper surface of the substrate; and the ohmic contact is deposed on the lower surface, the recessed hole and the recessed channels. Accordingly, a novel solar cell device having low electrical and thermal impedance is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the sectional side view showing the preferred embodiment according to the present invention;

FIG. 2 to FIG. 4 are the first to the third sectional bottom-up views showing the preferred embodiment; and

FIG. 5 is the view of the prior art.

### DESCRIPTION OF THE PREFERRED EMBODIMENT

The following description of the preferred embodiment is provided to understand the features and the structures of the present invention.

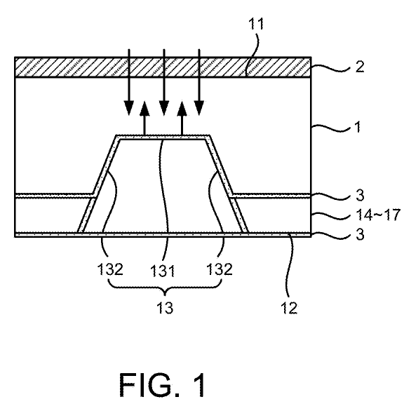

Please refer to FIG. 1, which is a sectional side view showing a preferred embodiment according to the present invention. As shown in the figure, the preferred embodiment is a solar cell device having low electrical and thermal impedance, comprising a substrate 1, a plurality of electric contact pads 2 and an ohmic contact 3.

The substrate 1 has an upper surface 11 and a lower surface 12; the lower surface 12 is corresponding to the upper surface 11; the lower surface 12 has a columnar recessed hole 13 and four recessed channels 14˜17 connected with openings of the recessed hole 13; the recessed channel 13 is made of an electric and thermal conductive material; the recessed hole 13 comprises a central recess 131 and a recess sidewall 132 surrounding the central recess 131; and, every one of the recessed channels 14˜17 has a depth not deeper than that of the recessed hole 13.

The electric contact pads 2 are deposed on at least a part of the upper surface 11.

The ohmic contact 3 is deposed on the lower surface 12, the recessed hole 13 and the recessed channels 14˜17. Thus, a novel solar cell device having low electrical and thermal impedance is obtained.

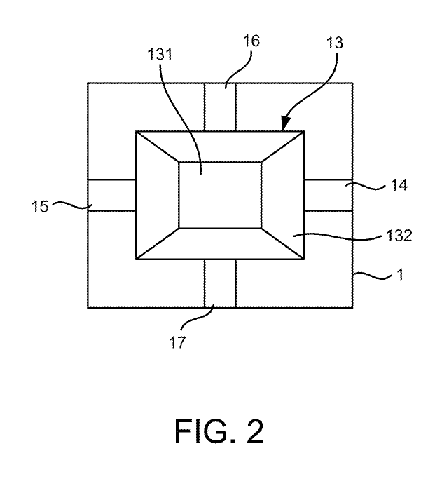

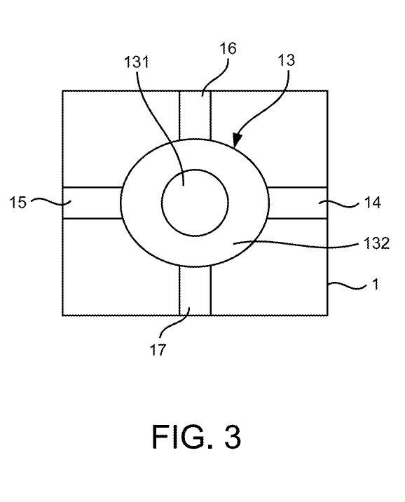

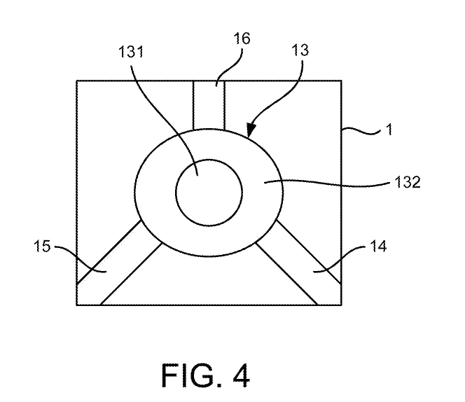

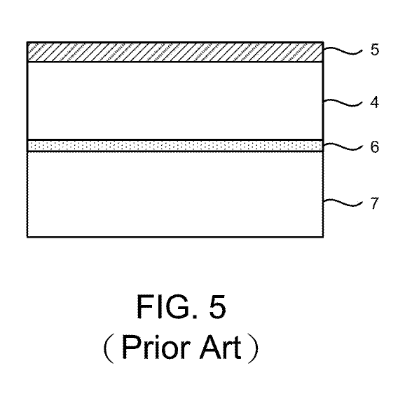

Please refer to FIG. 2 to FIG. 4, which are a first to a third sectional bottom-up views showing the preferred embodiment. As shown in the figures, on using the present invention, a recessed hole 13 is a square hole (in FIG. 2) or a circular hole (in FIG. 3); and recessed channels 14˜17 connected with openings of the recessed hole 13 are two channels (14,15 or 16,17) or three channels 14˜16 (in FIG. 4).

A light absorption region of the present invention is thus adhered to a heat dissipation device. Hence, an electric resistance and a thermal resistance are greatly reduced when the light absorption region is bonded to the recessed channels. Furthermore, the present invention has a strong structure and do not need extra bonding substrate while photon is reflected at back of the device; so more current is outputted efficiently and the present invention can be easily fabricated for mass production.

To sum up, the present invention is a solar cell device having low electrical and thermal impedance, where a light absorption region of the solar cell device is adhered to a heat dissipation device for reducing an electric resistance and a thermal resistance with a strong structure and a high efficiency; and the present invention can be easily fabricated for mass production.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A solar cell device having low electrical and thermal impedance, comprising
a substrate, said substrate having an upper surface and a lower surface, said lower surface being corresponding to said upper surface, said substrate having a recessed hole on said lower surface, said recessed hole having openings connected with four recessed channels, said recessed hole comprising a central recess and a recess sidewall, said recess sidewall surrounding said central recess;
a plurality of electric contact pads, said electric contact pads being deposed on said upper surface of said substrate; and
an ohmic contact, said ohmic contact being deposed on said lower surface, said recessed hole and said recessed channels.

2. The solar cell device according to claim 1, wherein said recessed hole is a square hole.

3. The solar cell device according to claim 1, wherein said recessed hole is a circular hole.

4. The solar cell device according to claim 1, wherein said recessed channel is made of an electric and thermal conductive material.

5. The solar cell device according to claim 1, wherein said recessed hole has openings connected with two recessed channels.

6. The solar cell device according to claim 1, wherein said recessed hole has openings connected with three recessed channels.

7. The solar cell device according to claim 1, wherein said recessed channel has a depth not deeper than that of said recessed hole.
